(19) United States
(12) Patent Application Publication
(10) Pub. No.: US 2002/0140012 A1
(43) Pub. Date: Oct. 3, 2002

(54) Semiconductor structures and devices for detecting far-infrared light and methods for fabricating same

(75) Inventor: Ravindranath Droopad, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola, Inc.

(21) Appl. No.: 09/822,499

(22) Filed: Mar. 30, 2001

(51) Int. Cl. H01L 29/76; H01L 29/94; H01L 31/062; H01L 31/113; H01L 31/119

(52) U.S. Cl. 257/295

(57) ABSTRACT

High-quality epitaxial layers of narrow-bandgap monocrystalline semiconductor materials can be grown overlying monocrystalline substrates (22), such as large silicon wafers, by forming a compliant substrate for growing the monocrystalline layers. One way to achieve the formation of a compliant substrate includes first growing a monocrystalline oxide layer (24) on a silicon wafer. The oxide layer may be spaced apart from the silicon wafer by an amorphous interface layer (28) of silicon oxide. The amorphous interface layer (28) dissipates strain and permits the growth of a high-quality monocrystalline oxide layer. The oxide layer (24) is lattice-matched to both the underlying silicon wafer and the overlying monocrystalline semiconductor material layer (26). Any lattice mismatch between the oxide layer (24) and the underlying silicon substrate (22) is relieved by the amorphous interface layer (28). Optical structures, such as far-infrared detectors and emitters, can be grown on high-quality, epitaxial, narrow-bandgap compound semiconductor materials to create highly reliable devices at reduced costs.

### FIELD OF THE INVENTION

This invention relates generally to semiconductor structures and devices and to a method for their fabrication and, more specifically, to light-detecting structures, such as far-infrared detectors, formed using compound materials from Groups III-V and/or Groups II-VI of the periodic table of the elements.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and bandgap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on substrates such as germanium, silicon, and various insulators. These attempts generally have been unsuccessful because lattice mismatches between the host crystal and the grown crystal have produced monocrystalline material layers of low crystalline quality.

If a large-area thin film of high-quality monocrystalline material were available at low cost, a variety of semiconductor devices could be advantageously fabricated either in or on that film relatively inexpensively, when compared to the cost of fabricating such devices either directly on a bulk wafer of semiconductor material or in an epitaxial film of such material on a bulk wafer of semiconductor material. In addition, if a thin film of high-quality monocrystalline material could be achieved on a bulk wafer, such as a silicon wafer, an integrated device structure could be fabricated which benefited from the best properties of both the silicon substrate and the high-quality monocrystalline material.

For certain optoelectronic applications, large-area detectors of light emitted in the infrared region of the electromagnetic spectrum are highly desirable. In general, warm or hot objects emit radiation in the infrared region with light wavelengths of up to about 12 μm. Emitted radiation at ambient temperature is in the spectral region above 3 μm. Since atmospheric absorption is negligible in the 3-5 μm and 8-12 μm wavelength ranges, these spectral regions represent an “atmospheric window” in which infrared detection devices would prove most advantageous. Narrow-bandgap semiconductor materials are potentially capable of detecting radiation emitted within these spectral regions. However, as illustrated in FIG. 16, certain semiconductor materials which both exhibit favorably narrow bandgaps and can sense or emit medium to long wavelengths of light in the infrared region also tend to have lattice constants that are substantially larger (i.e., in the range of about 6.0-6.5 Å) than the lattice constants of commonly used large-area substrates, such as bulk silicon, which has a lattice constant of approximately 5.4 Å.

Accordingly, a need exists for a semiconductor structure that provides an epitaxial, narrow-bandgap semiconductor material on a large-area substrate. Moreover, a need exists for a process of fabricating such a structure. In other words, there is a need for the formation of a monocrystalline substrate that is compliant with a high-quality, narrow-bandgap, monocrystalline material layer so that true, two-dimensional growth can be achieved for the formation of high-quality optical structures, devices, and integrated circuits having epitaxial monocrystalline material layers capable of detecting infrared light having wavelengths that are within the atmospheric window. Additionally, there is a need for semiconductor structures which permit far-infrared detection circuitry to be fabricated on the same silicon substrate, resulting in the monolithic integration of the detectors with the silicon circuitry.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 graphically illustrates the relationship between maximum attainable film thickness and lattice mismatch between a host crystal and a grown crystalline overlayer;

FIG. 5 illustrates a high-resolution Transmission Electron Micrograph of a structure including a monocrystalline accommodating buffer layer;

FIG. 6 illustrates an X-ray diffraction spectrum of a structure including a monocrystalline accommodating buffer layer;

FIG. 7 illustrates a high-resolution Transmission Electron Micrograph of a structure including an amorphous oxide layer;

FIG. 8 illustrates an X-ray diffraction spectrum of a structure including an amorphous oxide layer;

FIG. 9 illustrates schematically, in cross-section, the formation of a device structure in accordance with an embodiment of the invention;

FIG. 10 illustrates schematically, in cross-section, the formation of a device structure in accordance with another embodiment of the invention;

FIG. 11 illustrates schematically, in cross-section, the formation of a device structure in accordance with a further embodiment of the invention;

FIG. 12 illustrates schematically, in cross-section, the formation of a device structure in accordance with still another embodiment of the invention;

FIG. 13 illustrates schematically, in cross-section, the formation of a device structure in accordance with yet another embodiment of the invention;

FIG. 14 illustrates schematically, in cross-section, the formation of a device structure in accordance with a further embodiment of the invention;

FIG. 15 illustrates schematically, in cross-section, the formation of yet another embodiment of a device structure in accordance with the invention;

FIG. 16 graphically illustrates the relationship between the bandgap, lattice constant, and wavelength parameters of exemplary semiconductor materials.

Skilled artisans will appreciate that elements in the figures are illustrated for simplicity and clarity and have not necessarily been drawn to scale. For example, the dimensions of some of the elements in the figures may be exaggerated relative to other elements to enhance understanding of the various embodiments of the present invention.

### DETAILED DESCRIPTION OF EXEMPLARY EMBODIMENTS

The following disclosure presents and describes various exemplary embodiments in sufficient detail to enable those skilled in the art to practice the invention, and it should be understood that other embodiments may be realized without departing from the spirit and scope of the invention. Thus, the following detailed description is presented for purposes of illustration only, and not of limitation, and the scope of the invention is defined solely by the appended claims.

Preliminarily, as used herein, the term “monocrystalline” shall have the meaning commonly used within the semiconductor industry. The term shall refer to materials that are a single crystal or that are substantially a single crystal and shall include those materials having a relatively small number of defects, such as dislocations and the like, as are commonly found in substrates of silicon, germanium, or mixtures of silicon and germanium, as well as epitaxial layers of these materials, as commonly found in the semiconductor industry. Additionally, as used herein, “lattice constant” refers to the distance between atom centers for two atoms located on one side of the cube which embodies the unit cell of the crystalline material. Further, as used herein, the term “perovskite” is intended to comprise, but not be limited to, compounds or materials exhibiting a general crystal structure of stoichiometry (A,B)MO₃, where A is an alkali metal or alkaline-earth metal; B is optional and, if present, is an alkali metal or alkalineearth metal; M is at least one transition metal; and O is oxygen. Moreover, the term “perovskite” is intended to comprise, but not be limited to, non-stoichiometric crystalline compounds or materials exhibiting a crystal structure of the general form (A_{z}B_{1-z})₁₊ₓMO₃₊ₓ (where x is greater than O and z ranges from 0 to 1), where A is an alkali metal or alkaline-earth metal; B is optional and, if present, is an alkali metal or alkaline-earth metal; M is at least one transition metal; and 0 is oxygen. It also should be understood that while particular perovskite materials (such as alkaline-earth metal titanates, zirconates, hafnates, tantalates, vanadates, ruthenates, and niobates; lanthanum aluminates; and lanthanum scandium oxides for example) may be used to illustrate various aspects and embodiments of the present invention, these examples are illustrative only and are not intended to be restrictive.

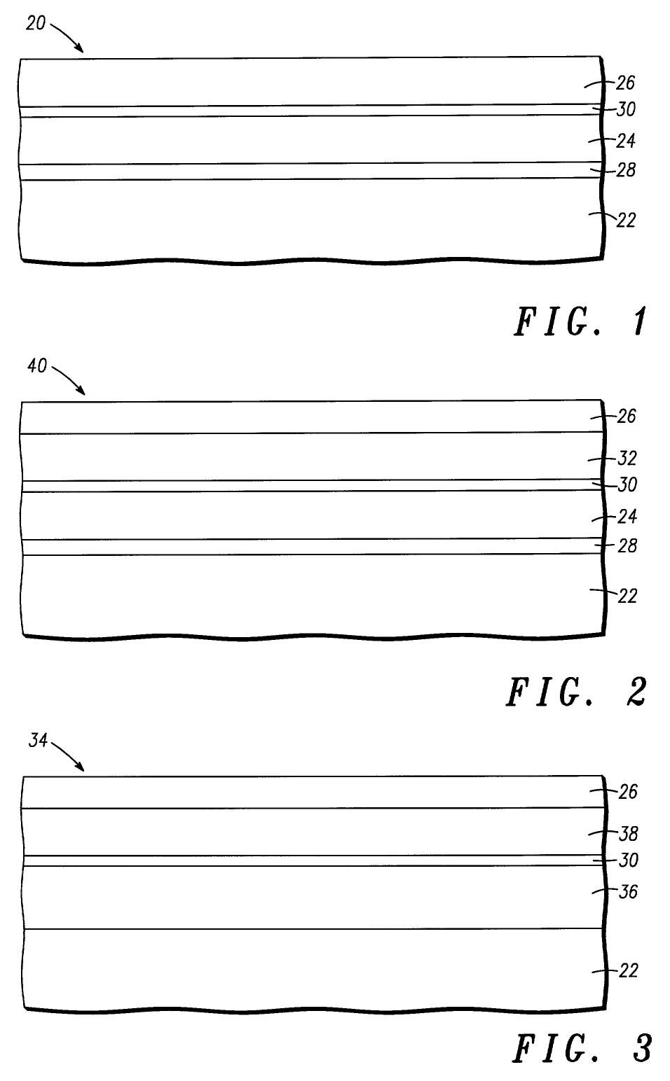

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and, by doing so, aids in the growth of a high crystalline quality accommodating buffer layer.

Substrate 22, in accordance with an embodiment of the invention, is a monocrystalline elemental semiconductor or compound semiconductor wafer, preferably of large diameter. The wafer can comprise, for example, a material from Group IV of the periodic table and preferably comprises a material from Group IVA. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium and, most preferably, is a high-quality monocrystalline silicon wafer, as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer 24 by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. If such strain is not relieved by the amorphous intermediate layer, the strain may cause defects in the crystalline structure of the accommodating buffer layer. Defects in the crystalline structure of the accommodating buffer layer, in turn, would likely compromise the crystalline quality of monocrystalline material layer 26. Material layer 26 may comprise an elemental semiconductor material, a compound semiconductor material, or any other type of semiconductor material, such as metal or non-metals. Preferably, however, material layer 26 comprises a compound semiconductor material.

Accommodating buffer layer 24 is preferably a monocrystalline oxide or nitride material selected for its crystalline compatibility with both the underlying substrate and the overlying material layer. For example, the material could be an oxide or nitride having a lattice structure closely matched to the lattice structures of both the substrate and the subsequently applied monocrystalline material layer. Materials that are suitable for the accommodating buffer layer include metal oxides, such as the alkaline-earth metal titanates, alkaline-earth metal zirconates, alkaline-earth metal hafnates, alkaline-earth metal tantalates, alkaline-earth metal ruthenates, alkaline-earth metal niobates, and alkaline-earth metal vanadates; perovskite oxides, such as alkaline-earth metal tin-based perovskites; and lanthanide series oxides, such as lanthanum aluminate, lanthanum scandium oxide, and gadolinium oxide. Additionally, various nitrides, such as gallium nitride, aluminum nitride, and boron nitride, may also be used for the accommodating buffer layer. Most of these materials are insulators, though others may be conductors, such as strontium ruthenate for example. Generally, these materials are metal oxides or metal nitrides, and, more particularly, these metal oxides or nitrides typically include at least two different metallic elements. In some specific applications, the metal oxides or nitrides may include three or more different metallic elements.

Amorphous interface layer 28 is preferably an oxide formed by the oxidation of the surface of substrate 22 and, more preferably, is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor material which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples of such compound semiconductor materials include gallium arsenide (GaAs), gallium indium arsenide (GaInAs), gallium aluminum arsenide (GaAlAs), indium phosphide (InP), cadmium sulfide (CdS), mercury cadmium telluride (HgCdTe), zinc selenide (ZnSe), zinc sulfur selenide (ZnSSe), and the like. However, monocrystalline material layer 26 may also comprise other semiconductor materials, metals, or nonmetal materials which are used in the formation of semiconductor structures, devices, and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 atomic monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer layer and the amorphous interface layer, which layers may or may not amalgamate. Thus, layer 36 may comprise one or two amorphous layers. Formation of amorphous layer 36 between substrate 22 and additional monocrystalline layer 26 (subsequent to the formation of layer 38) relieves lattice strain between layers 22 and 38 and provides a true compliant substrate for subsequent processing, such as the formation of monocrystalline material layer 26 for example.

The processes described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers, because this process permits the relaxation of any strain in layer 26.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include Group IV monocrystalline semiconductor materials or monocrystalline compound semiconductor materials.

In accordance with one embodiment of the present invention, additional monocrystalline layer 38 serves as both an anneal cap during layer 36 formation and a template for subsequent monocrystalline layer 26 formation. Accordingly, layer 38 is preferably thick enough to provide a suitable template for layer 26 growth (at least one atomic monolayer) and thin enough to allow layer 38 to form as a substantially defect free monocrystalline material.

In accordance with another embodiment of the invention, additional monocrystalline layer 38 comprises monocrystalline material (e.g. a material discussed above in connection with monocrystalline layer 26) that is thick enough to permit the formation of devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting illustrative examples show various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the <100> plane. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃, where the value of z ranges from 0 to 1, and the amorphous intermediate layer is a layer of silicon oxide (SiO,) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the compound semiconductor layer from the substrate to obtain the desired electrical and optical properties. Layers thicker than about 100 nm usually provide little additional benefit while increasing cost unnecessarily; however, thicker layers may be fabricated if needed. The amorphous intermediate layer of silicon oxide can have a thickness of about 0.5-5 nm and preferably has a thickness of about 1 to about 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to about 10 μm. The thickness generally depends upon the application for which the layer is being prepared. To facilitate the epitaxial growth of the gallium arsenide or aluminum gallium arsenide on the monocrystalline oxide, a template layer is formed by capping the oxide layer. The template layer is preferably about 1-10 atomic monolayers of Ti-As, Sr—O—As, Sr—Ga—O, or Sr—Al—O. By way of a preferred example, 1-2 atomic monolayers of Ti—As or Sr—Ga—O have been successfully demonstrated to grow GaAs layers.

### EXAMPLE 2

In accordance with a further embodiment of the invention, monocrystalline substrate 22 is a silicon substrate as described above. The accommodating buffer layer is a monocrystalline oxide of strontium zirconate, barium zirconate, strontium hafnate, or barium hafnate, in either a cubic or orthorhombic phase, with an amorphous intermediate layer of silicon oxide formed at the interface between the silicon substrate and the accommodating buffer layer. The accommodating buffer layer can have a thickness of about 2-100 nm. Preferably, the accommodating buffer layer has a thickness of at least about 5 nm, to ensure adequate crystalline and surface quality, and is formed of a monocrystalline SrZrO₃, BaZrO₃, SrHfO₃, BaSnO₃, or BaHfO₃. For example, a monocrystalline oxide layer of BaZro₃ grown at a temperature of about 700 degrees C. results in a crystalline oxide lattice structure exhibiting a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide (AlInAs), or aluminum gallium indium arsenic phosphide (AlGaInAsP) having a thickness of about 1 nm to about 10 μm. A suitable template for this structure is about 1-10 atomic monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P) and preferably is about 1-2 atomic monolayers of one of these materials. By way of an example, for a barium zirconate accommodating buffer layer, the surface is terminated with about 1-2 atomic monolayers of zirconium followed by deposition of about 1-2 atomic monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure as well as a lattice mismatch to <100> InP of less than about 2.5% and preferably of less than about 1%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where the value of x ranges from 0 to 1, having a thickness of about 2-100 nm and preferably a thickness of about 5-15 nm. Where the monocrystalline material layer comprises a compound semiconductor material, the II-VI compound semiconductor material can be, for example, zinc selenide (ZnSe) or zinc sulfur selenide (ZnSSe). A suitable template for this material system includes about 1-10 atomic monolayers of zinc-oxygen (Zn-O) followed by about 1-2 atomic monolayers of an excess of zinc followed by the selenidation of zinc on the surface. Alternatively, a template can be, for example, about 1-10 atomic monolayers of strontium-sulfur (Sr-S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in Example 1. In addition, an additional buffer layer 32 serves to alleviate any strain that might result from a mismatch of the crystal lattice of the accommodating buffer layer and the lattice of the monocrystalline material. Buffer layer 32 can be a layer of germanium or a strain-compensated superlattice of GaAs, aluminum gallium arsenide (AlGaAs), indium gallium phosphide (InGaP), aluminum gallium phosphide (AlGaP), indium gallium arsenide (InGaAs), aluminum indium phosphide (AlInP), gallium arsenide phosphide (GaAsP), or indium gallium phosphide (InGaP). In accordance with one aspect of this embodiment, buffer layer 32 includes a GaAsₓP₁₋ₓ superlattice, where the value of x ranges from 0 to 1. In accordance with another aspect, buffer layer 32 includes an In_{y}Ga_{1-y}P superlattice, where the value of y ranges from 0 to 1. By varying the value of x or y, as the case may be, the lattice constant is varied from bottom to top across the superlattice to create a match between the lattice constants of the underlying oxide and the overlying monocrystalline material which, in this example, is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same as that described in Example 1. Alternatively, buffer layer 32 can be a layer of monocrystalline germanium having a thickness of about 1-50 nm and preferably a thickness of about 2-20 nm. In using a germanium buffer layer, a template layer having a thickness of about one atomic monolayer of either germanium-strontium (Ge—Sr) or germanium-titanium (Ge—Ti) can be used as a nucleating site for the subsequent growth of the monocrystalline material layer which, in this example, is a compound semiconductor material. The formed oxide layer is capped with either an atomic monolayer of strontium or an atomic monolayer of titanium to act as a nucleating site for the subsequent deposition of the monocrystalline germanium. The atomic monolayer of strontiun or titanium provides a nucleating site to which the first atomic monolayer of germanium can bond.

### EXAMPLE 5

This example also illustrates materials useful in a structure 40 as illustrated in FIG. 2. Substrate material 22, accommodating buffer layer 24, monocrystalline material layer 26, and template layer 30 can be the same as those described above in Example 2. In addition, additional buffer layer 32 is inserted between the accommodating buffer layer and the overlying monocrystalline material layer. The additional buffer layer, a monocrystalline material which in this instance comprises a semiconductor material, can be a graded layer of indium gallium arsenide (InGaAs) or indium aluminum arsenide (InAlAs), for example. In accordance with one aspect of this embodiment, additional buffer layer 32 includes InGaAs, where the indium composition varies from 0 to about 50%. The buffer layer preferably has a thickness of about 10-30 nm. Varying the composition of the buffer layer from GaAs to InGaAs serves to provide a lattice match between the underlying monocrystalline oxide material and the overlying layer of monocrystalline material which, in this example, is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with Example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃, where the value of z ranges from 0 to 1, which combine or mix, at least partially, during an anneal process to form amorphous oxide layer 36.

The thickness of amorphous layer 36 may vary from application to application and may depend on such factors as the desired insulating properties of layer 36, the type of monocrystalline material comprising layer 26, and the like. In accordance with one exemplary aspect of the present embodiment, layer 36 has a thickness of about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 atomic monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by both a lattice constant and a crystal orientation. In a similar manner, accommodating buffer layer 24 is also a monocrystalline material, and the crystal structure of that monocrystalline material is characterized by both a lattice constant and a crystal orientation. The lattice constants of the accommodating buffer layer and the monocrystalline substrate must be closely matched or, alternatively, must be such that rotation of the orientation of one crystal with respect to the orientation of the other crystal achieves a substantial match in lattice constants. In this context, the terms “substantially equal” and “substantially matched” mean that there is sufficient similarity between the lattice constants to permit the growth of a high quality crystalline layer on the underlying layer.

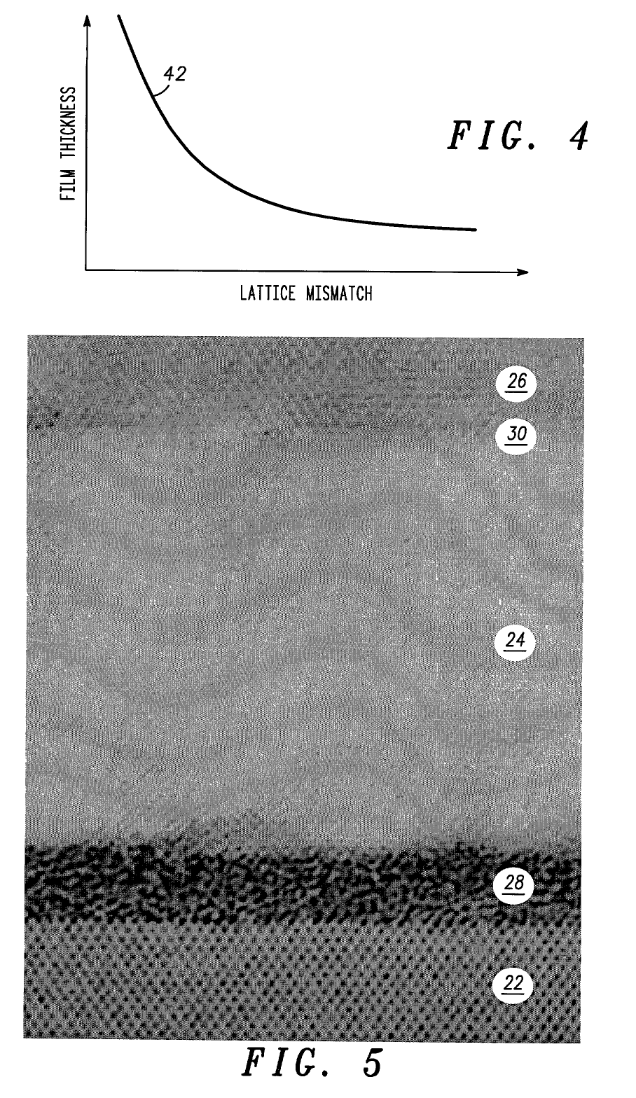

FIG. 4 graphically illustrates the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high-quality epitaxial layer on the host crystal. As the mismatch in lattice constants increases, the thickness of an achievable high-quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a <100> or <111> oriented monocrystalline silicon wafer, and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of a sufficiently thick amorphous interface layer 28, a silicon oxide layer in this example, tends to reduce strain in the titanate monocrystalline layer resulting from any mismatch in the lattice constants of the host silicon wafer and the grown titanate layer. Consequently, in accordance with an embodiment of the invention, a high-quality, thick, monocrystalline titanate layer is achievable.

Still referring to FIGS. 1-3, layer 26 is a layer of epitaxially grown monocrystalline material characterized by a lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, the monocrystalline accommodating buffer layer in this case, and the grown crystal is desired. This substantial matching of lattice constants may be achieved with properly selected materials and rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved by rotating the crystal orientation of the grown layer by 45° with respect to the crystal orientation of the host monocrystalline oxide. Similarly, if the host material is a strontium or barium zirconate, a strontium or barium hafnate, or barium tin oxide and the compound semiconductor material layer is indium phosphide, gallium indium arsenide, or aluminum indium arsenide, substantial matching of crystal lattice constants can be achieved by rotating the orientation of the grown crystal layer by 45° with respect to the host oxide crystal. In some instances, improved crystalline quality in the grown monocrystalline material layer can be achieved by depositing a crystalline semiconductor buffer layer between the host oxide and the grown monocrystalline material layer to reduce strain in the grown monocrystalline material layer that might result from small differences in lattice constants.

An exemplary process, in accordance with one embodiment of the invention, for fabricating a semiconductor structure, such as the structures depicted in FIGS. 1-3, begins by providing a monocrystalline layer, such as a monocrystalline material layer overlying either a substrate or another material layer or a monocrystalline semiconductor substrate comprising, for example, silicon and/or germanium. In accordance with one embodiment, a semiconductor substrate comprising a silicon wafer having a <100>orientation provides a suitable monocrystalline layer. The substrate may be oriented on axis or, at most, about 4° off axis. At least a portion of the semiconductor substrate has a bare surface, although other portions of the substrate, as described below, may encompass other structures. The term “bare” in this context means that the portion of the substrate surface has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention.

Epitaxial growth of a monocrystalline oxide layer overlying a monocrystalline substrate is facilitated by first removing the native oxide layer to expose the crystalline structure of the underlying substrate. An exemplary process is generally carried out by molecular beam epitaxy (MBE), although other processes, such as those outlined below, may also be used in accordance with the present invention. The native oxide can be removed by first thermally depositing a thin layer of strontium, barium, a combination of strontium and barium, or other alkaline-earth metals or combinations of alkaline-earth metals in an MBE apparatus. In the case where strontium is used, the substrate is then heated to a temperature of about 850° C. to cause the strontium to react with the native silicon oxide layer. The strontium serves to reduce the silicon oxide and leaves a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides favorable chemical and physical properties to nucleate the crystalline growth of an overlying layer.

In accordance with an alternate embodiment of the invention, the native silicon oxide can be reduced, and the substrate surface can be prepared for the growth of a monocrystalline oxide layer by depositing an alkaline earth oxide, such as strontium oxide, strontium barium oxide, or barium oxide, onto the substrate surface by MBE at a low temperature and by subsequently heating the structure to a temperature of about 850° C. At this temperature, a solid state reaction takes place between the strontium oxide and the native silicon oxide, causing the reduction of the native silicon oxide and creating an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C., and a monocrystalline oxide layer, such as a perovskite layer comprising an alkaline-earth metal titanate, such as strontium titanate, for example, is grown on the template layer by MBE. The MBE process is initiated by opening shutters in the MBE apparatus to expose sources of the appropriate elements, such as strontium, titanium, and oxygen sources in the case of growing strontium titanate. The ratio of the alkali metal or alkaline-earth metal to the transition metal is substantially stoichiometric. For example, in the case of strontium titanate, the ratio of strontium to titanium is about 1:1. The partial pressure of oxygen is initially set at a minimum value, such that the pressure in the deposition apparatus is less than about 5×10⁻⁷ mmbar, to grow a stoichiometric monocrystalline oxide layer. In the case of strontium titanate, the growth rate is about 0.3-0.5 nm per minute. After initiating growth of the monocrystalline oxide layer, the partial pressure of oxygen is increased above the initial minimum value to a value such that the pressure in the deposition apparatus is greater than or equal to about 10⁻⁶ mmbar. The overpressure of oxygen causes the growth of an amorphous silicon oxide layer at the interface between the underlying substrate and the growing perovskite layer. The growth of the silicon oxide layer results from the diffusion of oxygen through the growing perovskite layer to the interface where the oxygen reacts with silicon at the surface of the underlying substrate. The perovskite material grows as an ordered monocrystal whose orientation is rotated by 45° with respect to the ordered 2×1 crystalline structure of the underlying substrate. Strain that otherwise might exist in the perovskite layer due to slight mismatch in the lattice constants of the silicon substrate and the growing crystal is relieved by the amorphous silicon oxide intermediate layer.

After the perovskite layer has been grown to the desired thickness, the monocrystalline perovskite layer is capped by a template layer that is conducive to the subsequent growth of an epitaxial layer of a desired monocrystalline material. For example, to facilitate the subsequent growth of a monocrystalline compound semiconductor material layer of gallium arsenide, the strontium titanate monocrystalline layer can be capped by terminating the growth with about 1-2 atomic monolayers of titanium, about 1-2 atomic monolayers of titanium-oxygen, or about 1-2 atomic monolayers of strontium-oxygen. Following the formation of this capping layer, arsenic is deposited to form a Ti-As bond, a Ti-O-As bond, or a Sr-O-As bond. Any of these combination materials may form an appropriate template for the deposition and formation of a gallium arsenide monocrystalline layer. For example, following the formation of the template, gallium may subsequently be introduced with the arsenic, and gallium arsenide forms. Alternatively, gallium can be deposited on the capping layer to form a Sr-O-Ga bond, and arsenic may subsequently be introduced with the gallium to form the GaAs.

FIG. 5 is a high-resolution Transmission Electron Micrograph (TEM) of a semiconductor structure fabricated in accordance with one embodiment of the present invention. An accommodating buffer layer 24 of single-crystal SrTiO₃ is grown epitaxially on silicon substrate 22. During this growth process, amorphous interface layer 28 is formed, which relieves any strain that may be due to lattice mismatch. A GaAs compound semiconductor layer 26 is then grown epitaxially using template layer 30.

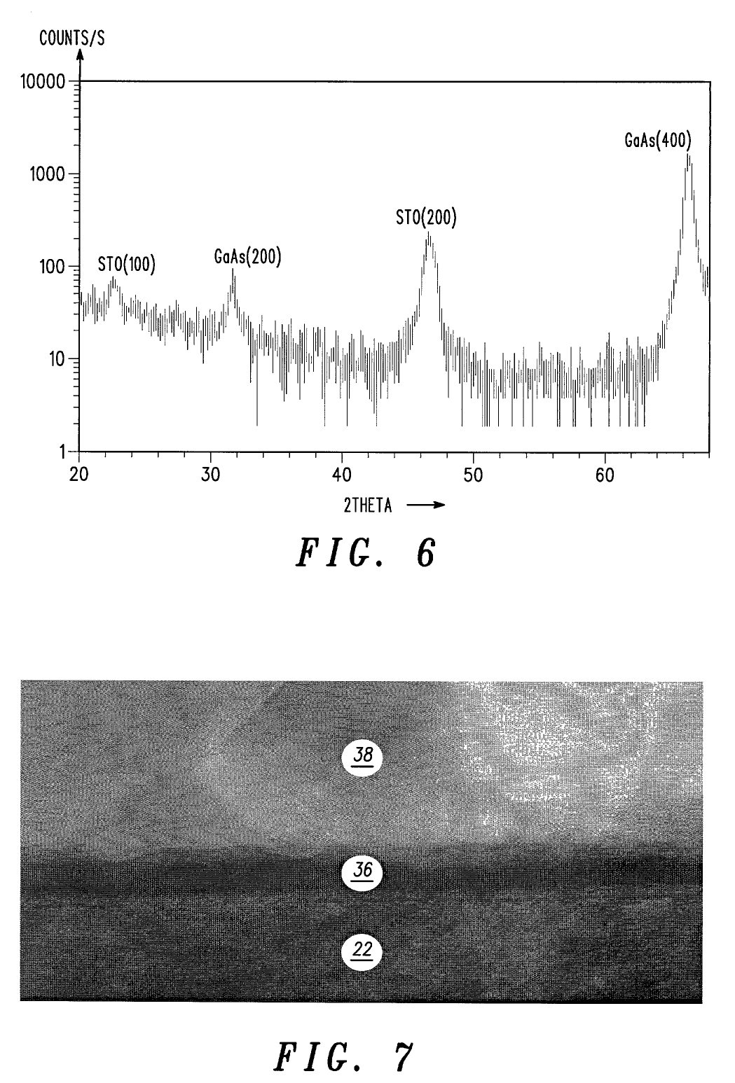

FIG. 6 illustrates an x-ray diffraction spectrum of a structure including a GaAs monocrystalline layer 26. The structure comprises GaAs grown on silicon substrate 22 using accommodating buffer layer 24. The peaks in the spectrum indicate that both the accommodating buffer layer 24 and the GaAs compound semiconductor layer 26 are single-crystal layers having a <100> orientation.

The structure illustrated in FIG. 2 can be formed by the process discussed above, supplemented with an additional buffer layer deposition step. The buffer layer is formed overlying the template layer prior to deposition of the monocrystalline material layer. If the buffer layer is a monocrystalline material comprising a compound semiconductor superlattice, such a superlattice can be deposited, by MBE for example, on the template described above. Alternatively, if the buffer layer is a monocrystalline material layer comprising a layer of germanium, the above-described process is modified by capping the strontium titanate monocrystalline layer with a final layer of either strontium or titanium and then by depositing germanium to react with the strontium or titanium. The germanium buffer layer then can be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to the growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environments) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26 may be employed to deposit layer 38.

FIG. 7 is a high-resolution TEM of a semiconductor structure fabricated in accordance with the embodiment of the invention illustrated in FIG. 3. In Accordance with this embodiment, an accommodating buffer layer of single crystal SrTiO₃ is grown epitaxially on silicon substrate 22. During this growth process, an amorphous interface layer forms as described above. Next, additional monocrystalline layer 38 comprising a compound semiconductor layer of GaAs is formed above the accommodating buffer layer, and the accommodating buffer layer is exposed to an anneal process to form amorphous oxide layer 36.

FIG. 8 illustrates an x-ray diffraction spectrum of a structure including an additional monocrystalline layer 38. This structure comprises a GaAs compound semiconductor layer and an amorphous oxide layer 36 formed on silicon substrate 22. The peaks in the spectrum indicate that the GaAs compound semiconductor layer 38 is a single crystal and is <100> oriented. The lack of peaks around 40 to 50 degrees indicates that layer 36 is amorphous.

The above-described process illustrates the formation of a semiconductor structure including a silicon substrate, an overlying oxide layer, and a monocrystalline material layer comprising a gallium arsenide compound semiconductor layer using molecular beam epitaxy. The process can also be carried out by using chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by such processes, other monocrystalline accommodating buffer layers, such as alkaline-earth metal titanates, zirconates, hafnates, tantalates, vanadates, ruthenates, and niobates; perovskite oxides, such as alkaline-earth metal tin-based perovskites; and lanthanide series oxides, such as lanthanum aluminate, lanthanum scandium oxide, and gadolinium oxide can also be grown. Moreover, such process may also facilitate the deposition of other monocrystalline material layers comprising other III-V and II-VI monocrystalline compound semiconductors, semiconductors, metals and non-metals overlying the monocrystalline oxide accommodating buffer layer.

Each of the variations of the monocrystalline material layer and the monocrystalline oxide accommodating buffer layer uses an appropriate template for initiating the growth of the monocrystalline material layer. For example, if the accommodating buffer layer is an alkaline-earth metal zirconate, the oxide can be capped by a thin layer of zirconium. The deposition of zirconium can be followed by the deposition of arsenic or phosphorus to react with the zirconium as a precursor to the deposition of indium gallium arsenide, indium aluminum arsenide, or indium phosphide, respectively. Similarly, if the monocrystalline oxide accommodating buffer layer is an alkaline-earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen, and barium titanate can be capped with a layer of barium or barium and oxygen. Each of these depositions can be followed by the deposition of arsenic or phosphorus to react with the capping material to form a template for the deposition of a monocrystalline material layer comprising compound semiconductor materials, such as indium gallium arsenide, indium aluminum arsenide, or indium phosphide.

One application of the present invention includes the use of the semiconductor structures and processes for fabricating semiconductor structures described above in the fabrication of a variety of optoelectronic devices, including far-infrared detectors, Hall effect sensors, far-infrared light emitting diodes (LEDs) and laser diodes (LDs), and vision enhancement devices, such as night vision devices. Far-infrared devices operable within the 3-5 μm and 8-12 μm wavelength range of the electromagnetic spectrum may be fabricated using a gallium-arsenic-indium-antimony (Ga—As—In—Sb) material system. Using materials in this system, structures including epitaxial monocrystalline material layers with incrementally decreasing bandgaps and sensitivity to infrared light of increasing wavelengths can be formed on a semiconductor substrate. Since the cost associated with the fabrication of these types of devices varies in direct proportion to the cost of the initial substrate used to form the infrared light-sensing structures, manufacturing constraints demand the development of less costly alternatives to using GaAs or the available narrow-bandgap substrates, such as InAs and InSb, as a starting substrate. One reason for the higher costs associated with using these materials as an initial substrate is the much smaller diameter of such wafers in comparison to wafers comprising a silicon substrate. A smaller wafer diameter necessarily limits the number of chips that can be formed from a single compound semiconductor wafer. Accordingly, in order to overcome this shortcoming, structures such as those described above with reference to FIGS. 1-3 can be used to create a monocrystalline compound semiconductor substrate for building optoelectronic devices, such as far-infrared detectors and emitters as well as Hall effect sensors.

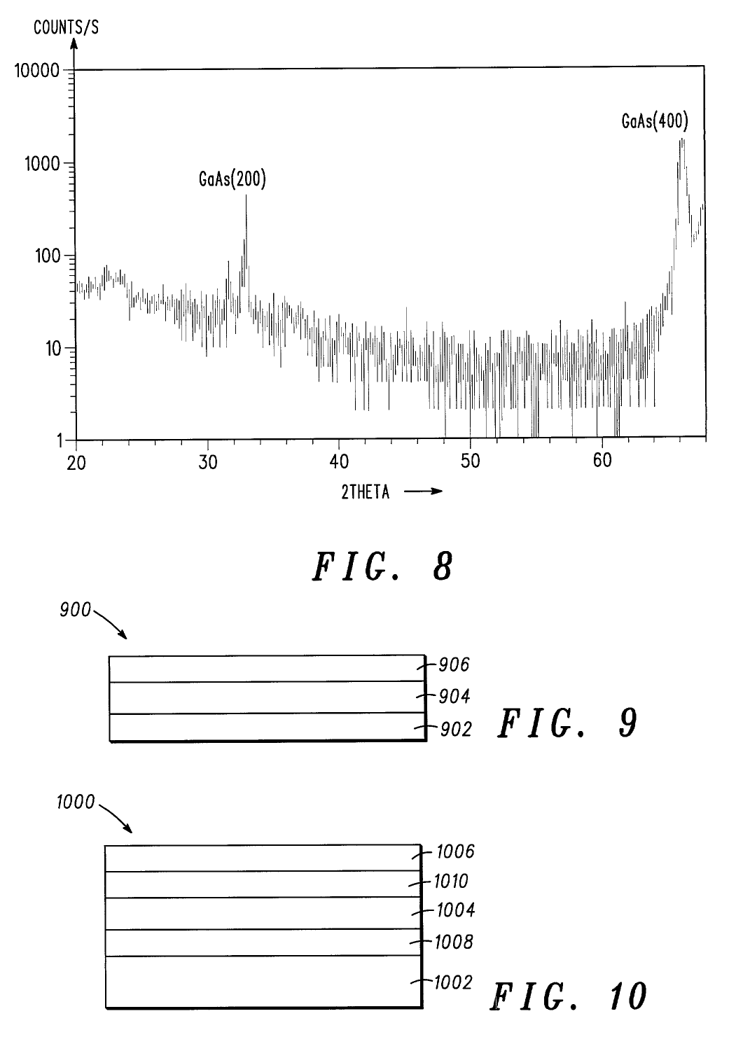

A cross-sectional view of an exemplary embodiment of a far-infrared light-sensing structure in accordance with the present invention is shown in FIG. 9. Far-infrared sensing structure 900 includes a monocrystalline semiconductor substrate 902, a monocrystalline oxide layer 904 epitaxially grown over substrate 902, and a monocrystalline semiconductor material layer 906 epitaxially grown over substrate 904. Substrate 902 may comprise any of the substrates previously described with reference to substrate 22 of FIGS. 1-3. That is, substrate 902 may comprise a material from Group IV of the periodic table and preferably comprises a material from Group IVA. Oxide layer 904 may comprise any of the oxide materials described above with reference to accommodating buffer layer 24 of FIGS. 1-3. Oxide layer 904 is preferably closely lattice-matched to layer 906. Any of the deposition or growth methods described above in connection with layer 24 may be employed to deposit layer 904.

In one embodiment, substrate 902 comprises a <100> oriented silicon wafer, and oxide layer 904 comprises a monocrystalline oxide material having a lattice constant which is suitably matched with the lattice constants of both the underlying substrate 902 and the overlying semiconductor material layer 906. In another exemplary embodiment, oxide layer 904 comprises a gradated layer of perovskite material, such as barium titanate, strontium titanate, or barium strontium titanate, wherein the lattice constant of oxide layer 904 is gradually changed during the deposition process, such as an MBE process for example, to increase its compatibility with the lattice constant of overlying semiconductor material layer 906. In still another exemplary embodiment, oxide layer 904 comprises a layer of barium potassium bismuth oxide ((Ba, K) BiO₃). In this embodiment, depending upon the composition of overlying semiconductor material layer 906, the crystal orientation of the layer of (Ba, K) BiO₃ may be suitably rotated relative to the underlying substrate to better match the lattice constant of the subsequently grown semiconductor material layer 906. In one embodiment, the layer of (Ba, K) BiO₃ is rotated by about 45 degrees relative to the crystal orientation of the underlying substrate.

Monocrystalline semiconductor material layer 906 comprises a compound semiconductor material layer of narrow-bandgap material which is capable of sensing far-infrared light of wavelengths within the 3-5 μm and 8-12 μm spectral regions. Layer 906 may be selected from any of the materials described above with reference to layer 26 of FIG. 1-3. Preferably, layer 906 comprises materials from Groups III-V or II-VI of the periodic table of the elements. Additionally, layer 906 may comprise alpha tin, a metastable form of tin that has a bandgap close to zero. The bandgap of layer 906 ranges from about 0 eV to about 0.75 eV and preferably ranges from about 0 eV to about 0.35 eV. In one embodiment, layer 906 comprises a compound semiconductor material such as gallium arsenide (GaAs), gallium antinomide (GaSb), gallium indium arsenide (GaInAs), gallium indium antinomide, indium arsenide (InAs), indium antinomide (InSb), indium arsenic antinomide (InAs_{z}Sb_{1-z}, where the value of z ranges from 0 to 1), mercury cadmium telluride (HgₓCd₁₋ₓTe, where the value of x ranges from 0 to 0.5), or a material comprising alpha tin. Layer 906 can have a thickness of about 2 nm to about 10 μm and preferably has a thickness of about 100 nm to about 3 μm. The thickness of layer 906 generally depends upon the application for which the layer is being prepared. Any of the deposition or growth methods described above in connection with layer 26 may be employed to deposit layer 906.

FIG. 10 illustrates a cross-sectional view of another exemplary embodiment of a light-sensing structure formed on a compliant oxide layer. Light-sensing structure 1000 includes a monocrystalline semiconductor substrate 1002, a monocrystalline oxide layer 1004 epitaxially grown over substrate 1002, and a narrow-bandgap monocrystalline semiconductor material layer 1006 epitaxially grown over oxide layer 1004 and capable of sensing far-infrared light. Layers 1002 and 1004 may comprise any of the materials described above with reference to layers 902 and 904, respectively, of FIG. 9. Layer 1006 may comprise any of the semiconductor materials described above with reference to layer 906 of FIG. 9. The bandgap of layer 1006 ranges from about 0 eV to about 0.75 eV and preferably ranges from about 0 eV to about 0.35 eV.

Structure 1000 further includes an amorphous interface layer 1008 positioned between substrate 1002 and oxide layer 1004. Amorphous interface layer 1008 may comprise any of the materials previously described with reference to amorphous interface layers 28 or 36 of FIGS. 1-3. Amorphous interface layer 1008 may be an oxide formed by the oxidation of the surface of substrate 1002 and preferably is composed of a silicon oxide. Like layer 28 and 36 of FIGS. 1-3, amorphous interface layer 1008 is of a thickness sufficient to relieve strain attributed to mismatches between the lattice constants of substrate 1002 and oxide layer 1004, which lattice constants are typically in the range of about 0.38 nm to about 0.43 nm. By relieving any strain in the oxide layer 1004, amorphous interface layer 1008 aids in the growth of a high-quality monocrystalline oxide layer. Any of the deposition or growth methods described above in connection with layers 28 or 36 may be employed to deposit layer 1008.

Structure 1000 may also include a template layer 1010 positioned between the oxide layer 1004 and compound semiconductor material layer 1006. As described above with reference to template layer 30 of FIGS. 1-3, template layer 1010 aids in initiating epitaxial growth of semiconductor layer 1006 on the oxide layer 1004. Template layer 1010 may comprise any of the materials described above with reference to template layer 30 of FIGS. 1-3, but the composition of template layer 1010 depends upon the materials selected for oxide layer 1004 and semiconductor material layer 1006. In one embodiment, a template layer 1010 may be formed by capping oxide layer 1004 to facilitate the epitaxial growth of monocrystalline semiconductor material layer 1006 overlying oxide layer 1004. The template layer 1010 preferably comprises about 1-10 atomic monolayers comprising a combination of one or more elements of the oxide layer 1004 and one or more elements of the compound semiconductor material layer 1006. Any of the deposition or growth methods described above in connection with layer 30 may be employed to deposit layer 1010.

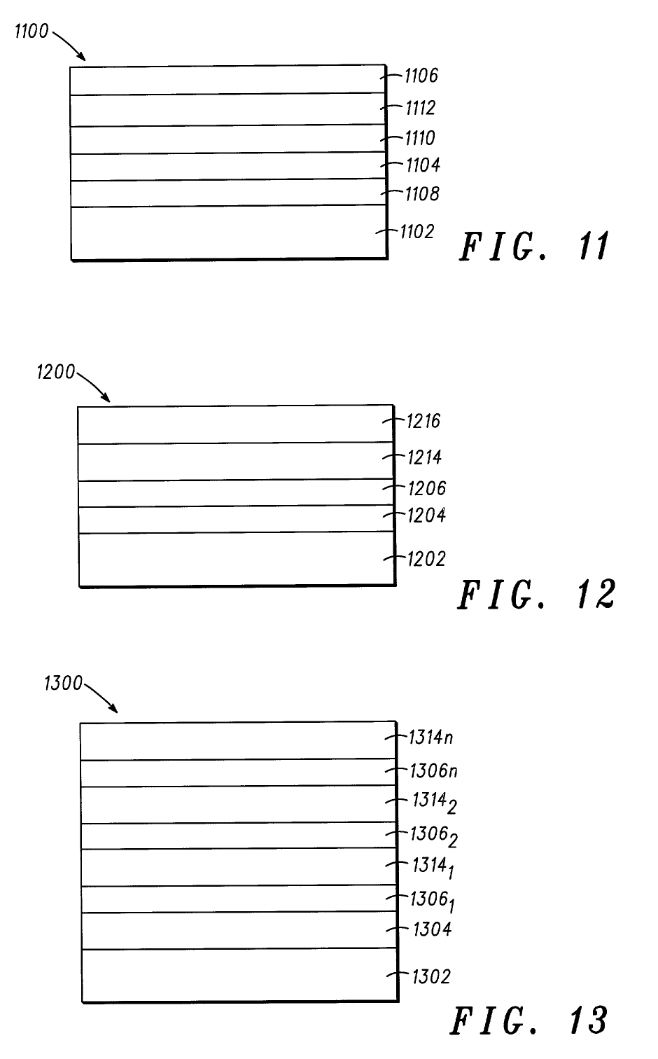

FIG. 11 illustrates a cross-sectional view of a portion of an infrared light-sensing semiconductor structure 1100 in accordance with a further embodiment of the invention. Structure 1100 is similar to the previously described semiconductor structures 900 and 1000, except that a buffer layer 1112 is positioned between monocrystalline oxide layer 1104 and semiconductor material layer 1106. Layers 1102 and 1104 may comprise any of the materials described above with reference to layers 902 and 904, respectively, of FIG. 9. Layer 1106 may comprise any of the semiconductor materials described above with reference to layer 906 of FIG. 9. The bandgap of layer 1106 ranges from about 0 eV to about 0.75 eV and preferably ranges from about 0 eV to about 0.35 eV.

In one embodiment, as shown in FIG. 11, buffer layer 1112 is positioned between template layer 1110 and monocrystalline semiconductor material layer 1106. The buffer layer 1112 provides lattice compensation when the lattice constant of the oxide layer 1104 cannot be adequately matched to the overlying monocrystalline semiconductor material layer 1106. Preferably, buffer layer 1112 comprises the same material as semiconductor material layer 1106. In one embodiment, after a thin buffer layer 1112 is grown over oxide layer 1104, the structure 1100 undergoes a rapid thermal anneal process to amorphize the oxide layer 1104 and provide a true compliant substrate for subsequent epitaxial growth of semiconductor material layer 1106. Preferably, buffer layer 1112 comprises about 1 to about 5000 atomic monolayers and more preferably comprises about 50 to about 1000 atomic monolayers. Any of the deposition or growth methods described above in connection with layer 32 may be employed to deposit layer 1112.

FIG. 12 illustrates a cross-sectional view of an infrared light-sensing semiconductor structure in accordance with a further embodiment of the present invention. Structure 1200 may comprise a monocrystalline semiconductor substrate 1202; a monocrystalline oxide layer 1204 epitaxially grown over substrate 1202; a monocrystalline semiconductor material layer 1206 epitaxially grown over oxide layer 1204; a compositionally gradated semiconductor material layer 1214 epitaxially grown over layer 1206; and an active semiconductor material layer 1216 epitaxially grown over layer 1214. Substrate 1202 and oxide layer 1204 may comprise any of the previously described substrate and oxide materials, respectively. Layers 1206, 1214, and 1216 comprise independently selected Group III-V or II-VI compound semiconductor materials. The bandgap of layer 1216 ranges from about 0 eV to about 0.75 eV and preferably ranges from about 0 eV to about 0.35 eV.

Exemplary materials from which layers 1206, 1214, and 1216 may be selected include GaAs, GaSb, InAs, InSb, GaInₓAs₁₋ₓ (where the value of x ranges from 0 to 1), GaIn_{y}Sb_{1-y} (where the value of y ranges from 0 to 1), InAs_{z}Sb_{1-z} (where the value of z ranges from 0 to 1), HgₓCd₁₋ₓTe (where the value of x ranges from 0 to 0.5), and materials comprising alpha tin. In the cases of GaInₓAs₁₋ₓ and InAs_{z}Sb_{1-z}, for example, by varying the value of x or z, as the case may be, the lattice constant is varied from bottom to top across the superlattice to create a match between the lattice constants of the underlying oxide and the overlying monocrystalline material which, in this example, is a compound semiconductor material. The compositions of other compound semiconductor materials may be varied similarly to manipulate the lattice constant of the layer in a like manner.

In this embodiment, layers 1206 and 1216 are epitaxially grown in a manner that creates a compositionally gradated layer 1214 positioned between layer 1206 and layer 1216. For example, as layer 1206 of a compound semiconductor material, such as GaAs, is grown, another element, such as indium for example, may be gradually introduced into the reaction in increasing quantities, while the content of Ga is correspondingly decreased. In this manner, the composition of the grown semiconductor material gradually changes from GaAs to InAs, producing a layer 1214 of a compositionally gradated ternary compound semiconductor material, GaInAs in this example, positioned between semiconductor layer 1206 and active semiconductor layer 1216. Depending upon the materials used for layers 1206 and 1216, the compositionally gradated layer 1214 positioned between layers 1206 and 1216 may be a quaternary compound semiconductor material, such as GaAsInSb for example. The superlattice period can have a thickness of about 1 nm to about 10 nm and preferably has a thickness of about 2 nm to about 5 nm.

The semiconductor material layer 1206 comprises a thickness of about 20 nm to about 5 μm and preferably comprises a thickness of about 0.25 μm to about 2 μm. The compositionally gradated layer 1214 of semiconductor material comprises a thickness of about 10 nm to about 1000 nm and preferably comprises a thickness of about 50 nm to about 500 nm. The active semiconductor material layer 1216 comprises a thickness of about 2 nm to about 10 μm and preferably comprises a thickness of about 10 nm to about 5 μm. In this manner, the structure 1200 achieves improved lattice-matching between layers 1206 and 1216 as well as greater strain relaxation.

FIG. 13 illustrates a cross-sectional view of an infrared light-sensing semiconductor structure in accordance with yet another embodiment of the present invention. Structure 1300 may comprise a monocrystalline semiconductor substrate 1302; a monocrystalline oxide layer 1304 epitaxially grown over substrate 1302; monocrystalline semiconductor material layers 1306ₗ-1306ₙ; and active semiconductor material layers 1314ₗ-1314ₙ. Substrate 1302 and oxide layer 1304 may comprise any of the previously described substrate and oxide materials, respectively. Layers 1306 and 1314 comprise independently selected Group III-V or II-VI compound semiconductor materials. The bandgap of active semiconductor material layers 1314ₗ-1314ₙ ranges from about 0 eV to about 0.75 eV and preferably ranges from about 0 eV to about 0.35 eV. Exemplary materials from which layers 1306 and 1314 may be selected include GaAs, GaSb, InAs, InSb, GaInₓAs₁₋ₓ (where the value of x ranges from 0 to 1), GaIn_{y}Sb_{1-y} (where the value of y ranges from 0 to 1), InAs_{z}Sb_{1-z} (where the value of z ranges from 0 to 1), and HgₓCd₁₋ₓTe (where the value of x ranges from 0 to 0.5) for example.

In this embodiment, layers 1306 and 1314 are epitaxially grown as discrete, alternating layers of at least two different semiconductor materials to create a strained layer superlattice which gradually effects a change in the lattice constant of the structure. For example, if layer 1306 comprises GaAs and layer 1314 comprises InAs, a discrete layer 1306₁ of GaAs may be grown overlying oxide layer 1304. Then, a discrete layer 1314₁ of InAs may be grown over the layer 1306₁ of GaAs. Next, a layer 1306₂ of GaAs is grown over layer 1314₁, and a layer 1314₂ of InAs is grown over layer 1306₂, et cetera. This process may continue, until a desired number (n) of alternating material layers have been grown or deposited. As the strained layer superlattice is grown, the thickness of the second semiconductor material layer 1314, comprised of InAs in this example, is gradually varied from bottom to top across the superlattice relative to the thickness of the first semiconductor material layer 1306, which comprises GaAs in this example. Structure 1300 comprises a strained layer superlattice comprising about 5 to about 100 layers and preferably about 10 to about 50 layers.

In another exemplary embodiment, layer 1306 comprises InAs and layer 1314 comprises InSb. A discrete layer 1306₁ of InAs may be grown overlying oxide layer 1304. Then, a discrete layer 1314₁ of InSb may be grown over the layer 1306₁ of InAs. Next, a layer 1306₂ of InAs is grown over layer 1314₁, and a layer 1314₂ of InSb is grown over layer 1306₂, et cetera. This process may continue, until a desired number (n) of alternating material layers have been grown or deposited. As the strained layer superlattice is grown, the thickness of the second semiconductor material layer 1314, comprised of InSb in this example, is gradually varied from bottom to top across the superlattice relative to the thickness of the first semiconductor material layer 1306, which comprises InAs in this example.

In one embodiment, the first semiconductor material layer 1306₁ comprises a thickness of about 10 Å to about 50 Å and preferably comprises a thickness of about 20 Å to about 30 Å. The second semiconductor material layer 1314₁ comprises a thickness of about 10 Å to about 50 Å and preferably comprises a thickness of about 20 Å to about 30 Å. In one embodiment, as the superlattice is grown, the thickness of the first semiconductor material is gradually decreased across the superlattice while the thickness of the second semiconductor material remains constant (at a thickness of about 20-30 Å, for example), such that final first semiconductor material layer 1306ₙ comprises a thickness of about 0 Å to about 20 Å and preferably comprises a thickness of about 5 Å to about 15 Å. In another embodiment, as the superlattice is grown, the thickness of the second semiconductor material is gradually decreased across the superlattice while the thickness of the first semiconductor material remains constant (at a thickness of about 20-30 Å, for example), such that final first semiconductor material layer 1306ₙ comprises a thickness of about 0 Å to about 20 Å and preferably comprises a thickness of about 5 Å to about 15 Å. In a further embodiment, the thickness of the second semiconductor material is gradually increased across the superlattice while the thickness of the first semiconductor material remains decreased, such that the combined thickness of semiconductor material layers 1306 and 1314 is about 10 Å to about 50 Å and preferably comprises a thickness of about 15 Å to about 30 Å. In yet another embodiment, the thickness of the first semiconductor material is gradually decreased across the superlattice while the thickness of the second semiconductor material is gradually increased across the superlattice, such that the combined thickness of semiconductor material layers 1306 and 1314 is about 10 Å to about 50 Å and preferably comprises a thickness of about 15 Å to about 30 Å. For convenience and brevity, the strained-layer superlattice is described herein with reference to two alternating material layers. However, as will be appreciated, the superlattice may be fabricated with any number of different material layers, depending upon the particular application.

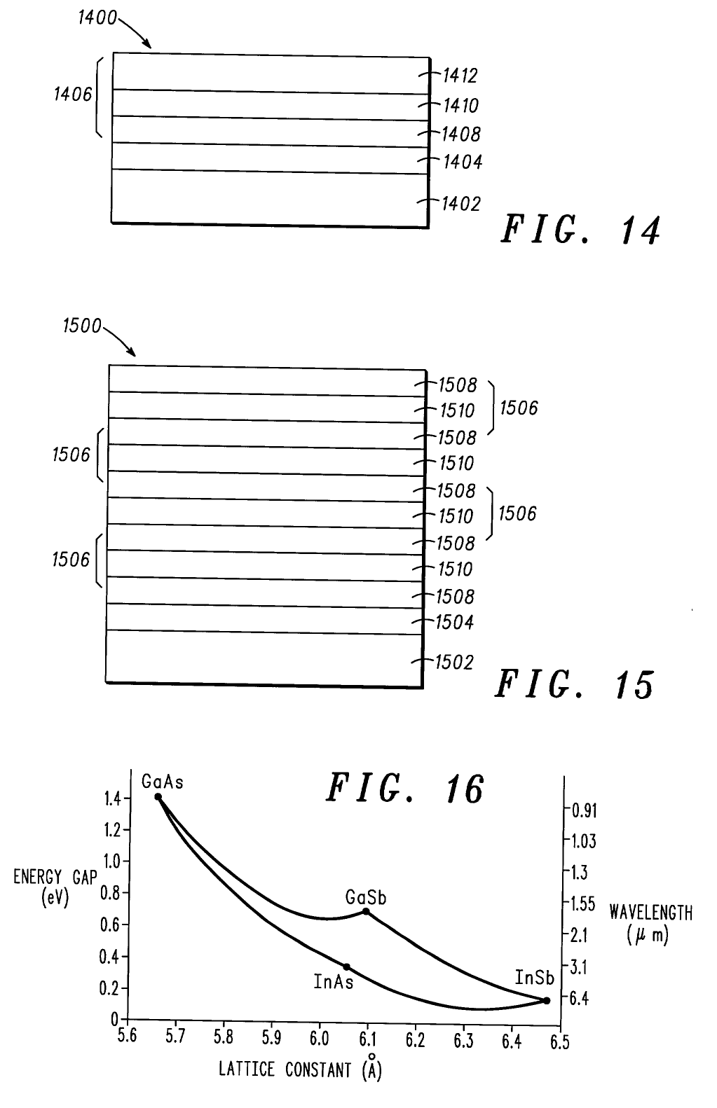

In accordance with another aspect of the present invention, FIG. 14 illustrates a cross-sectional view of an exemplary light-emitting structure 1400, which includes a quantum well for achieving optical transitions within the infrared region of the electromagentic spectrum. Light-emitting structure 1400 comprises a monocrystalline semiconductor substrate 1402 underlying an epitaxially grown monocrystalline oxide layer 1404. A monocrystalline quantum well structure 1406 capable of emitting infrared light within the atmospheric window is then epitaxially grown over oxide layer 1404 to create structure 1400. Quantum well 1406 includes three layers of compound semiconductor material, wherein an active layer 1410 is sandwiched between barrier layers 1408 and 1412. The bandgap of active layer 1410 ranges from about 0 eV to about 0.75 eV and preferably ranges from about 0 eV to about 0.35 eV. Quantum well 1406 is grown epitaxially, in layers, over oxide layer 1404. Specific examples of the light-emitting structure illustrated by FIG. 14 include a structure where the quantum well 1406 includes active layer 1410, comprised of InAs for example, sandwiched between barrier layers 1408 and 1412 which are each comprised of GaSb for example. The thickness of active layer 1410 is preferably between about 5 nm and about 20 nm.

Oxide layer 1404 may comprise any of those materials previously described with reference to layer 24 in FIGS. 1-2. Oxide layer 1404 preferably comprises SrTiO₃. Further, as previously explained with reference to FIG. 3, oxide layer 1404 may comprise an amorphous oxide layer, such as layer 36 in FIG. 3, which is formed by annealing an amorphous oxide layer and a monocrystalline oxide layer. Further, as will be appreciated by those skilled in the art, quantum well 1406 may comprise multiple quantum wells.

FIG. 15 shows another exemplary embodiment of the present invention directed to an infrared light-emitting structure having multiple quantum wells. Infrared light-emitting structure 1500 includes a substrate 1502, an oxide layer 1504, and multiple quantum wells 1506. Each quantum well 1506 includes an active layer 1510 sandwiched between two barrier layers 1508. The bandgap of active layer 1510 preferably is smaller than that of the barrier layers 1508. Active layers 1510 and barrier layers 1508 may be comprised of exemplary materials such as those described above with reference to layers 1410 and 1408 in FIG. 14. However, in structures having multiple quantum wells, those layers making up the wells preferably have a thickness of about 5 nm to about 15 nm, which is typically a lesser thickness than the other layers comprising the structure. It should also be noted that infrared light-emitting structure 1500 may comprise many different infrared light-emitting devices, including light emitting diodes (LED) and lasers.

The structures described above with reference to FIGS. 9-15 may be fabricated by any of the processes previously described in connection with the structures depicted in FIGS. 1-3. For example, suitable processes for forming the structures shown in FIGS. 9-15 include molecular beam epitaxy (MBE), chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

In the foregoing specification, the invention has been described with reference to specific embodiments. However, it will be appreciated that various modifications and changes can be made without departing from the scope of the present invention as set forth in the claims below. The specification and figures are to be regarded in an illustrative manner, rather than a restrictive one, and all such modifications are intended to be included within the scope of present invention. Accordingly, the scope of the invention should be determined by the appended claims and their legal equivalents, rather than by the examples given above. For example, the steps recited in any of the method or process claims may be executed in any order and are not limited to the order presented in the claims.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises”, “comprising”, or any other variation thereof, are intended to cover a non-exclusive inclusion, such that a process, method, article, or apparatus that comprises a list of elements does not include only those elements but may include other elements not expressly listed or inherent to such process, method, article, or apparatus. Further, no element described herein is required for the practice of the invention unless expressly described as “essential” or“critical”.

We claim:

1. A semiconductor structure comprising:
a monocrystalline substrate;
a monocrystalline oxide layer formed on said substrate; and
a monocrystalline material layer formed overlying said monocrystalline oxide layer, wherein said monocrystalline material layer comprises a material which has a narrow bandgap and senses infrared light.

2. The semiconductor structure of claim 1, wherein said monocrystalline substrate comprises material selected from the group consisting of silicon, germanium, silicon carbide, indium phosphide, silicon germanium, gallium arsenide, and indium arsenide.

3. The semiconductor structure of claim 1, wherein said monocrystalline substrate comprises silicon.

4. The semiconductor structure of claim 1, wherein said monocrystalline oxide layer is closely lattice-matched to said monocrystalline material layer.

5. The semiconductor structure of claim 1, wherein said monocrystalline oxide layer comprises a perovskite material.

6. The semiconductor structure of claim 5, wherein said monocrystalline oxide layer comprises a gradated perovskite material.

7. The semiconductor structure of claim 5, wherein said perovskite material comprises an alkaline-earth metal titanate.

8. The semiconductor structure of claim 1, wherein said monocrystalline oxide layer comprises (Ba, K) BiO₃.

9. The semiconductor structure of claim 8, wherein said monocrystalline substrate is characterized by a first crystal orientation and said monocrystalline oxide layer is characterized by a second crystal orientation, and wherein the second crystal orientation is rotated with respect to the first crystal orientation.

10. The semiconductor material of claim 1, wherein said monocrystalline material layer comprises compound semiconductor material selected from the group consisting of Group III-V compounds, mixed Group III-V compounds, Group II-VI compounds, mixed Group II-VI compounds, and materials comprising alpha tin.

11. The semiconductor structure of claim 1, wherein said monocrystalline material layer comprises material selected from the group consisting of InAs, InSb, GaInAs, GaInSb, InAsSb, HgCdTe, and material comprising alpha tin.

12. The semiconductor structure of claim 1, wherein said monocrystalline material layer senses infrared light within the atmospheric window.

13. The semiconductor structure of claim 1, wherein said monocrystalline material layer has a bandgap of less than about 0.35 eV.

14. The semiconductor structure of claim 1, further comprising an amorphous interface layer positioned between said monocrystalline substrate and said monocrystalline oxide layer.

15. The semiconductor structure of claim 14, wherein said amorphous interface layer comprises silicon oxide.

16. The semiconductor structure of claim 1, further comprising a template layer positioned between said monocrystalline oxide layer and said monocrystalline material layer.

17. The semiconductor structure of claim 16, wherein said template layer comprises one or more elements of said monocrystalline oxide layer and one or more elements of said monocrystalline material layer.

18. The semiconductor structure of claim 1, further comprising a buffer layer positioned between said monocrystalline oxide layer and said monocrystalline material layer.

19. The semiconductor structure of claim 18, wherein said buffer layer is positioned between a tempate layer and said monocrystalline material layer.

20. The semiconductor structure of claim 19, wherein said buffer layer comprises a material also selected for said monocrystalline material layer.

21. The semiconductor structure of claim 20, wherein the structure is heat-treated to amorphize said monocrystalline oxide layer.

22. A semiconductor structure comprising:
a monocrystalline substrate;
a monocrystalline oxide layer formed on said substrate;
a monocrystalline material layer formed overlying said monocrystalline oxide layer;
a compositionally gradated monocrystalline material layer overlying said monocrystalline material layer; and
an active monocrystalline material layer overlying said compositionally gradated monocrystalline material layer, wherein said active monocrystalline material layer comprises a material which has a narrow bandgap and senses infrared light.

23. The semiconductor structure of claim 22, wherein said compositionally gradated monocrystalline material layer and said active monocrystalline material layer each comprises compound semiconductor material independently selected from the group consisting of Group III-V compounds, mixed Group III-V compounds, Group II-VI compounds, and mixed Group II-VI compounds.

24. The semiconductor structure of claim 22, wherein said compositionally gradated monocrystalline material layer comprises material selected from the group consisting of GaInAs, GaInSb, InAsSb, and GaAsSb.

25. The semiconductor structure of claim 22, wherein said active monocrystalline material layer comprises material selected from the group consisting of, InAs, InSb, GaInAs, GaInSb, InAsSb, HgCdTe, and material comprising alpha tin.

26. The semiconductor structure of claim 22, wherein said monocrystalline substrate comprises a Group IV semiconductor material.

27. The semiconductor structure of claim 22, wherein said monocrystalline substrate comprises silicon.

28. The semiconductor structure of claim 22, wherein said monocrystalline oxide layer comprises a perovskite material.

29. The semiconductor structure of claim 28, wherein said monocrystalline oxide layer comprises a gradated perovskite material.

30. The semiconductor structure of claim 28, wherein said perovskite material comprises an alkaline-earth metal titanate.

31. The semiconductor structure of claim 22, wherein said active monocrystalline material layer senses infrared light within the atmospheric window.

32. The semiconductor structure of claim 22, wherein said active monocrystalline material layer has a bandgap of less than about 0.35 eV.

33. A semiconductor structure comprising:
a monocrystalline substrate;
an amorphous interface layer overlying said monocrystalline substrate;
an monocrystalline oxide layer overlying said amorphous interface layer; and
a monocrystalline material layer formed overlying said monocrystalline oxide layer, wherein said monocrystalline material layer has a narrow bandgap and senses infrared light.

34. The semiconductor structure of claim 33, wherein said monocrystalline substrate comprises a Group IV semiconductor material.

35. The semiconductor structure of claim 34, wherein said monocrystalline substrate comprises silicon.

36. The semiconductor structure of claim 35, wherein said amorphous interface layer comprises silicon oxide.

37. The semiconductor structure of claim 36, wherein said monocrystalline oxide layer is closely lattice-matched to said monocrystalline material layer.

38. The semiconductor structure of claim 36, wherein said monocrystalline oxide layer comprises a perovskite material.

39. The semiconductor structure of claim 38, wherein said monocrystalline oxide layer comprises a gradated perovskite material.

40. The semiconductor structure of claim 39, wherein said gradated perovskite material comprises an alkaline-earth metal titanate.

41. The semiconductor structure of claim 36, wherein said monocrystalline oxide layer comprises (Ba, K) BiO₃.

42. The semiconductor structure of claim 41, wherein said monocrystalline substrate is characterized by a first crystal orientation and said monocrystalline oxide layer is characterized by a second crystal orientation, and wherein the second crystal orientation is rotated with respect to the first crystal orientation.

43. The semiconductor material of claim 36, wherein said monocrystalline material layer comprises compound semiconductor material selected from the group consisting of Group III-V compounds, mixed Group III-V compounds, Group II-VI compounds, mixed Group II-VI compounds, and materials comprising alpha tin.

44. The semiconductor structure of claim 36, wherein said monocrystalline material layer comprises material selected from the group consisting of InAs, InSb, GaInAs, GaInSb, InAsSb, HgCdTe, and material comprising alpha tin.

45. The semiconductor structure of claim 36, wherein said monocrystalline material layer senses infrared light within the atmospheric window.

46. The semiconductor structure of claim 36, wherein said monocrystalline material layer has a bandgap of less than about 0.35 eV.

47. The semiconductor structure of claim 36, further comprising a template layer positioned between said monocrystalline oxide layer and said monocrystalline material layer.

48. The semiconductor structure of claim 47, wherein said template layer comprises one or more elements of said monocrystalline oxide layer and one or more elements of said monocrystalline material layer.

49. The semiconductor structure of claim 47, further comprising a buffer layer positioned between said monocrystalline oxide layer and said monocrystalline material layer.

50. The semiconductor structure of claim 49, wherein said buffer layer is positioned between a template layer and said monocrystalline material layer.

51. The seminconductor structure of claim 50, wherein said buffer layer comprises a material also selected for said monocrystalline material layer.

52. The seminconductor structure of claim 51, wherein the structure is heat-treated to amorphize said monocrystalline oxide layer.

53. A semiconductor structure comprising:
a monocrystalline substrate;
an monocrystalline oxide layer formed on said substrate; and
a plurality of alternating material layers of at least two different monocrystalline materials, wherein said plurality of alternating material layers are formed over said monocrystalline oxide layer, and wherein at least one of said different monocrystalline materials has a narrow bandgap and senses infrared light.

54. The structure of claim 53, wherein said plurality of alternating material layers comprises a strained-layer superlattice.

55. The semiconductor structure of claim 54, wherein said plurality of alternating material layers comprises a first monocrystalline material layer underlying a second monocrystalline material layer, and wherein a thickness of each of said first and second monocrystalline material layers is varied, relative to each other, across said superlattice.

56. The semiconductor structure of claim 55, wherein said thickness of said second monocrystalline material layer is gradually increased across said superlattice.

57. The semiconductor structure of claim 55, wherein said thickness of said first monocrystalline material layer is gradually decreased across said superlattice.

58. The semiconductor structure of claim 53, wherein each of said plurality of alternating material layers comprises compound semiconductor material independently selected from the group consisting of Group III-V compounds, mixed Group III-V compounds, Group II-VI compounds, and mixed Group II-VI compounds.

59. The semiconductor structure of claim 53, wherein each of said plurality of alternating material layers comprises compound semiconductor material independently selected from the group consisting of InAs, InSb, InAsSb, GaInAs, GaInSb, and GaAsSb.

60. The semiconductor structure of claim 53, wherein said monocrystalline substrate comprises a Group IV semiconductor material.

61. The semiconductor structure of claim 53, wherein said monocrystalline substrate comprises silicon.

62. The semiconductor structure of claim 53 wherein said monocrystalline oxide layer comprises a perovskite material.

63. The semiconductor structure of claim 62, wherein said monocrystalline oxide layer comprises a gradated perovskite material.

64. The semiconductor structure of claim 62, wherein said gradated perovskite material comprises an alkaline-earth metal titanate.

65. The semiconductor structure of claim 53 wherein at least one of said at least two different monocrystalline materials senses infrared light within the atmospheric window.

66. The semiconductor structure of claim 53, wherein said at least one of said at least two different monocrystalline materials has a bandgap of less than about 0.35 eV.

67. A semiconductor structure comprising:
a monocrystalline substrate;
an monocrystalline oxide layer overlying said substrate;
a monocrystalline quantum well structure overlying said monocrystalline oxide layer, wherein said quantum well structure senses infrared light.

68. The structure of claim 67, wherein said quantum well structure comprises a single quantum well.

69. The structure of claim 68, wherein said single quantum well comprises an active layer comprising at least one of InAs, InSb, InAsSb, and HgCdTe sandwiched between barrier layers comprising at least one of GaSb, InAs, InAsSb, and CdTe.

70. The structure of claim 69, wherein said active layer has a bandgap of less than about 0.35 eV.

71. The structure of claim 67, wherein said quantum well structure comprises multiple quantum wells.

72. The structure of claim 71, wherein said multiple quantum wells comprise a plurality of active layers comprising at least one of InAs, InSb, InAsSb, and HgCdTe, wherein each active layer is sandwiched between barrier layers comprising at least one of GaSb, InAs, InAsSb, and CdTe.

73. The structure of claim 72, wherein each of said plurality of active layers has a bandgap of less than about 0.35 eV.

74. A process for fabricating an infrared light-sensing semiconductor device comprising:
providing a monocrystalline semiconductor substrate;
growing an epitaxial monocrystalline oxide layer over said substrate;
growing an epitaxial monocrystalline material layer over said monocrystalline oxide layer, wherein said monocrystalline material layer comprises a material which has a narrow bandgap and senses infrared light.

75. The process of claim 74, wherein the step of providing a monocrystalline semiconductor substrate comprises providing a substrate comprising material selected from the group consisting of silicon, germanium, silicon carbide, indium phosphide, silicon germanium, gallium arsenide, and indium arsenide.

76. The process of claim 74, wherein each of the steps of growing comprises growing by a process selected from the group consisting of molecular beam epitaxy, chemical vapor deposition, metal organic chemical vapor deposition, migration enhanced epitaxy, atomic layer epitaxy, physical vapor deposition, chemical solution deposition, and pulsed laser deposition.

77. The process of claim 74, wherein the step of growing an epitaxial monocrystalline oxide layer further comprises growing a perovskite material.

78. The process of claim 77, wherein the step of growing a perovskite material further comprises growing a gradated perovskite material layer such that a lattice constant of said perovskite material layer is gradually changed during a deposition process to match said lattice constant to a lattice constant of said monocrystalline material layer.

79. The process of claim 77, wherein the step of growing a perovskite material further comprises growing an epitaxial monocrystalline monocrystalline oxide layer comprising an alkaline-earth metal titanate.

80. The process of claim 79, wherein the step of growing a perovskite material comprises the step of growing an epitaxial monocrystalline oxide layer comprising at least one of BaTiO₃, SrTiO₃, and SrₓBa₁₋ₓTiO3 (where a value of x ranges from 0 to 1).

81. The process of claim 74, wherein the step of growing an epitaxial monocrystalline oxide layer further comprises growing a layer of (Ba, K) BiO₃.

82. The process of claim 81, wherein the step of growing a layer of (Ba, K) BiO₃ further includes rotating a crystal orientation of said layer of (Ba, K) BiO₃ relative to a crystal orientation of said monocrystalline semiconductor substrate.

83. The process of claim 81, wherein the step of rotating comprises rotating by about 45 degrees relative to said crystal orientation of said monocrystalline semiconductor substrate.

84. The process of claim 74, wherein the step of growing an epitaxial monocrystalline material layer further includes providing a monocrystalline material having a bandgap of less than about 0.35 eV.

85. The process of claim 74, wherein the step of growing an epitaxial monocrystalline material layer further includes providing a monocrystalline material selected from the group consisting of Group III-V compounds, mixed Group III-V compounds, Group II-VI compounds, mixed Group II-VI compounds, and materials comprising alpha tin.

86. The process of claim 74, wherein the step of growing an epitaxial monocrystalline material layer further includes providing a monocrystalline material selected from the group consisting of InAs, InSb, GaInAs, GaInSb, InAsSb, HgCdTe, and material comprising alpha tin.

87. The process of claim 74, wherein the step of providing a monocrystalline semiconductor substrate comprises the step of providing a substrate comprising silicon.

88. The process of claim 87, further comprising the step of forming an amorphous interface layer underlying said monocrystalline oxide layer during the step of growing an epitaxial monocrystalline oxide layer.

89. The process of claim 74, further comprising forming a template layer overlying said monocrystalline oxide layer.

90. The process of claim 89, wherein the step of forming a template layer further includes capping said monocrystalline oxide layer.

91. The process of claim 90, wherein the step of forming a template layer further includes providing a material comprising one or more elements of said monocrystalline oxide layer and one or more elements of said monocrystalline material layer.

92. The process of claim 74, further comprising growing a buffer layer over said monocrystalline oxide layer.

93. The process of claim 92, further comprising rapid thermal processing of the structure to amorphize said monocrystalline oxide layer.

94. The process of claim 92, wherein the step of growing a buffer layer further comprises providing a material also selected for a subsequently deposited monocrystalline material layer.

95. A process for fabricating an infrared light-sensing semiconductor device comprising:
providing a monocrystalline semiconductor substrate;
growing an epitaxial monocrystalline oxide layer over said substrate;
growing an epitaxial monocrystalline material layer over said monocrystalline oxide layer;
growing a compositionally gradated monocrystalline material layer over said monocrystalline material layer; and
growing an epitaxial active monocrystalline material layer over said compositionally gradated monocrystalline material layer, wherein said active monocrystalline material layer comprises a material which has a narrow bandgap and senses infrared light.

96. The process of claim 95, wherein the step of providing a monocrystalline semiconductor substrate comprises providing a substrate comprising material selected from the group consisting of silicon, germanium, silicon carbide, indium phosphide, silicon germanium, gallium arsenide, and indium arsenide.

97. The process of claim 95, wherein the step of providing a monocrystalline semiconductor substrate comprises the step of providing a substrate comprising silicon.

98. The process of claim 95, wherein each of the steps of growing comprises growing by a process selected from the group consisting of molecular beam epitaxy, chemical vapor deposition, metal organic chemical vapor deposition, migration enhanced epitaxy, atomic layer epitaxy, physical vapor deposition, chemical solution deposition, and pulsed laser deposition.

99. The process of claim 95, wherein the step of growing an epitaxial monocrystalline oxide layer further comprises growing a perovskite material layer.

100. The process of claim 99, wherein the step of growing a perovskite material layer further comprises growing an epitaxial monocrystalline monocrystalline oxide layer comprising an alkaline-earth metal titanate.

101. The process of claim 95, wherein the step of growing an epitaxial active monocrystalline material layer further includes providing an active monocrystalline material having a bandgap of less than about 0.35 eV.

102. The process of claim 95, wherein the step of growing an epitaxial active monocrystalline material layer further includes providing a material selected from the group consisting of Group III-V compounds, mixed Group III-V compounds, Group II-VI compounds, mixed Group II-VI compounds, and materials comprising alpha tin.

103. The process of claim 95, wherein the step of growing an epitaxial active monocrystalline material layer further includes providing a material selected from the group consisting of InAs, InSb, GaInAs, GaInSb, InAsSb, HgCdTe, and material comprising alpha tin.

104. The process of claim 95, wherein the step of growing a compositionally gradated monocrystalline material layer further includes providing a material selected from the group consisting of Group III-V compounds, mixed Group III-V compounds, Group II-VI compounds, and mixed Group II-VI compounds.

105. The process of claim 95, wherein the step of growing a compositionally gradated monocrystalline material layer further includes providing a material selected from the group consisting of GaInAs, GaInSb, InAsSb, and GaAsSb.

106. A process for fabricating an infrared light-sensing semiconductor device comprising:
providing a monocrystalline semiconductor substrate;
growing an epitaxial monocrystalline oxide layer over said substrate;
growing a plurality of alternating layers of at least two different monocrystalline materials over said monocrystalline oxide layer, wherein at least one of said different monocrystalline materials has a narrow bandgap and senses infrared light.

107. The process of claim 106, wherein the step of growing a plurality of alternating layers further comprises forming a strained-layer superlattice.

108. The process of claim 107, wherein the step of growing a plurality of alternating layers further comprises:
growing a first layer of a first monocrystalline material over said monocrystalline oxide layer;
growing a second layer of a second monocrystalline material over said first layer; and
subsequently growing alternating layers of said first and second monocrystalline materials, wherein a thickness of each of said first and second monocrystalline materials is varied, relative to each other, across said superlattice.

109. The process of claim 108, wherein the step of subsequently growing further comprises gradually increasing said thickness of said second monocrystalline material across said superlattice.

110. The process of claim 108, wherein the step of subsequently growing further comprises gradually decreasing said thickness of said first monocrystalline material across said superlattice.

111. The process of claim 106, wherein the step growing a plurality of alternating layers further comprises independently selecting a material for each alternating layer from the group consisting of Group III-V compounds, mixed Group III-V compounds, Group II-VI compounds, and mixed Group II-VI compounds.

112. The process of claim 106, wherein the step growing a plurality of alternating layers further comprises independently selecting a material for each alternating layer from the group consisting of GaSb, InAs, InSb, GaInAs, GaInSb, InAsSb, and HgCdTe.

113. The process of claim 106, wherein the step of providing a monocrystalline semiconductor substrate comprises providing a substrate comprising material selected from the group consisting of silicon, germanium, silicon carbide, indium phosphide, silicon germanium, gallium arsenide, and indium arsenide.

114. The process of claim 106, wherein the step of providing a monocrystalline semiconductor substrate comprises the step of providing a substrate comprising silicon.

115. The process of claim 106, wherein each of the steps of growing comprises growing by a process selected from the group consisting of molecular beam epitaxy, chemical vapor deposition, metal organic chemical vapor deposition, migration enhanced epitaxy, atomic layer epitaxy, physical vapor deposition, chemical solution deposition, and pulsed laser deposition.

116. The process of claim 106, wherein the step of growing an epitaxial monocrystalline oxide layer further comprises growing a perovskite material.

117. The process of claim 116, wherein the step of growing a perovskite material further comprises growing an epitaxial monocrystalline monocrystalline oxide layer comprising an alkaline-earth metal titanate.

118. The process of claim 106, wherein the step of growing a plurality of alternating layers further includes providing at least one material having a bandgap of less than about 0.35 eV.

119. A process for fabricating an infrared light-emitting device comprising:
providing a monocrystalline silicon substrate;
depositing an epitaxial monocrystalline oxide layer overlying said silicon substrate;
depositing an epitaxial first compound semiconductor material layer overlying said monocrystalline oxide layer, wherein said first compound semiconductor material layer comprises materials which are lattice-matched to said monocrystalline oxide layer;
depositing an epitaxial active compound semiconductor material layer overlying said first compound semiconductor material layer, wherein said active compound semiconductor material layer has a bandgap of less than about 0.35 eV and comprises materials which are lattice-matched to said first compound semiconductor material layer; and
depositing an epitaxial second compound semiconductor material layer overlying said active compound semiconductor material layer, thereby forming a quantum well structure configured to emit infrared light.

120. The process of claim 119, wherein the step of depositing an epitaxial active compound semiconductor material layer comprises depositing a compound semiconductor material selected from the group consisting of InAs, InSb, InAsSb, and HgCdTe.

121. The process of claim 119, wherein each of the steps of depositing comprises depositing by a process selected from the group consisting of molecular beam epitaxy, chemical vapor deposition, metal organic chemical vapor deposition, migration enhanced epitaxy, atomic layer epitaxy, physical vapor deposition, chemical solution deposition, and pulsed laser deposition.
